(19) United States
(12) Patent Application Publication
(10) Pub. No.: US 2009/0149027 A1
(43) Pub. Date: Jun. 11, 2009

(54) Method of Fabricating an Integrated Circuit

(76) Inventors: Daniel Koehler, Chemnitz (DE); Johannes Heitmann, Dresden (DE); Michael Obert, Dresden (DE)

Correspondence Address: SLATER & MATSIL, L.L.P., 17950 PRESTON ROAD, SUITE 1000, DALLAS, TX, 75252, US

(21) Appl. No.: 11/953,550

(22) Filed: Dec. 10, 2007

(51) Int. Cl. H01L 21/311

(52) U.S. Cl. 438/703; 257/E21.249

(57) ABSTRACT

Embodiments of the invention relate to a method of fabricating an integrated circuit, including etching of a layer that includes a high k material in the form of a metal oxide composition, wherein an etchant is used that includes a silicon halogen composition.

### BACKGROUND

Semiconductor devices are used in a variety of electronic applications, such as personal computers, cell phones, digital cameras, and other electronic equipment, as examples. Semiconductor devices are typically fabricated by sequentially depositing insulating (or dielectric) layers, conductive layers, and semiconductive layers of material over a semiconductor substrate, and patterning the various layers using lithography to form circuit components and elements thereon.

A transistor is an element that is utilized extensively in semiconductor devices. There may be millions of transistors on a single integrated circuit (IC), for example. A common type of transistor used in semiconductor device fabrication is a metal oxide semiconductor field effect transistor (MOSFET). Complementary MOS (CMOS) devices, use both positive and negative channel devices, e.g., a positive channel metal oxide semiconductor (PMOS) transistor and a negative channel metal oxide semiconductor (NMOS) transistor, in complimentary configurations. An NMOS device negatively charges so that the transistor is turned on or off by the movement of electrons, whereas a PMOS device involves the movement of electron vacancies.

The gate dielectric for MOSFET devices has in the past typically comprised silicon dioxide, which has a dielectric constant of about 3.9. However, as devices are scaled down in size, using silicon dioxide for a gate dielectric becomes a problem because of gate leakage current, which can degrade device performance. Therefore, there is a trend in the industry towards the development of the use of high dielectric constant (k) materials for use as the gate dielectric in MOSFET devices. High k gate dielectric development has been identified as one of the future challenges in the 2002 edition of International Technology Roadmap for Semiconductors (ITRS), which identifies the technological challenges and needs facing the semiconductor industry over the next 15 years.

### BRIEF DESCRIPTION OF THE DRAWINGS

In the accompanying drawings:

FIG. 1 illustrates a semiconductor structure fabricated with the method according to the invention;

FIG. 2 relates to a method according to an embodiment of the invention; and

FIG. 3 relates to a method according to another embodiment of the invention.

### DETAILED DESCRIPTION OF ILLUSTRATIVE EMBODIMENTS

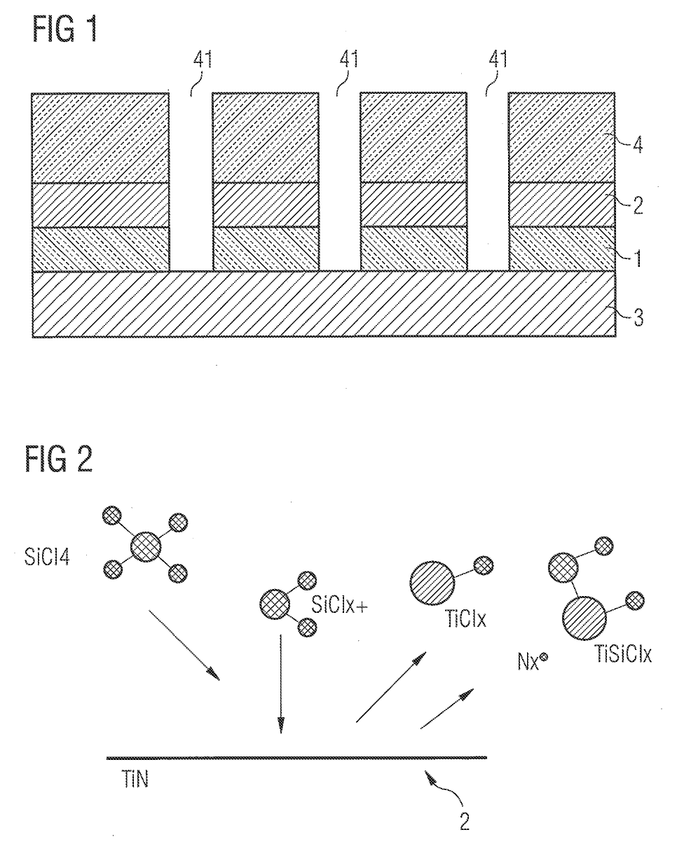

Referring to FIG. 1, a layer stack comprising layers 1 and 2 is created on a semiconductor substrate 3 (e.g., a silicon substrate). Layer 1 is formed by a high k material (or at least comprises such a material). It is noted that the term “high k” is a common technical term denominating a material which has a high dielectric constant compared to conventional dielectrics such as silicon oxide or silicon nitride. Examples of high k materials include transition metal oxides (e.g., hafnium oxide or zirconium oxide) and rare earth oxide compositions (such as ytterbium oxide). Other high k materials, however, are of course also covered by the invention.

Layer 2 (further layer), which is arranged on layer 1, is configured to be a diffusion barrier that thwarts a diffusion out of high k layer 1. In an example, layer 2 comprises titanium nitride. In another embodiment of the invention layer 2 is configured to be a conductive layer (i.e., it comprises a conductive material), wherein it can (but does not necessarily have to) act as a diffusion barrier at the same time.

In an embodiment of the invention the layer stack comprising layers 1 and 2 is to be used for the fabrication of a transistor, wherein the high k layer 1 is to be used as a high k gate dielectric of the transistor and layer 2 comprises a conductive material and constitutes a diffusion barrier between the high k gate dielectric and another layer (not shown) of a gate electrode stack of the transistor. However, the invention is not restricted to the fabrication of transistors but can be used for the fabrication of any integrated circuit that includes a high k material in the form of a metal oxide composition; e.g., capacitors of a semiconductor device.

FIG. 1 further illustrates that the layers 1 and 2 are structured using a mask layer 4 with openings 41 (which, e.g., are created lithographically). An etching step is performed such that openings are created in layer 1 and 2 in the region of the openings 41 of the mask. The etching is performed using an etchant that comprises a composition, wherein layer 1 and layer 2 are etched in one step using the silicon halogen etchant. In an embodiment of the invention the silicon halogen composition comprises a gaseous silicon chloride composition such as silicon tetrachloride. Other silicon halogen compositions, however, can also be used (e.g., silicon tetrafluoride).

In a further example, the etching is performed using a plasma to decompose the silicon halogen composition of the etchant such that a plasma containing silicon and halogen components is created. The plasma is created in a plasma chamber, e.g., using inductive coupling (ICP) or any other method known for plasma creation.

For example, a flow of about 20 sccm of a silicon tetrachloride gas (SiCl₄) is used. Further, the etchant can additionally comprise Cl₂ gas (e.g., with a flow of about 30 sccm) and an additional percentage of N₂ gas (e.g., with a flow of about 40 sccm). Exemplarily, a pressure of about 10 mTorr is used and a temperature in the region of an electrode of the plasma chamber (for plasma generation and on which the substrate can be arranged) is chosen to be approximately 50° C.

During the etching of high k layer 1 with the silicon halogen composition an intermediate composition in the form of a metal silicon oxide composition can be created. This intermediate composition, e.g., comprises hafnium silicide oxide in case layer 1 comprises hafnium oxide. A metal silicon oxide composition tends to have a higher etchability than its metal oxide counterpart such that the usage of a silicon halogen composition as etchant tends to provide higher etch rates.

FIG. 2 refers to an embodiment of the invention illustrating a possible etching mechanism. In this embodiment a layer structure similar to the one shown in FIG. 1, i.e., including a high k layer 1 and a barrier layer 2, is present. The barrier layer 2 is formed of titanium nitride (TiN).

The etchant that is used for etching layers 1 and 2 comprises a silicon halogen gas in the form of silicon tetrachloride, wherein a single silicon tetrachloride molecule (labelled SiC₄) is illustrated in FIG. 2. A plasma is ignited in the silicon tetrachloride gas to decompose the silicon tetrachloride such that reactive SiClₓ⁻ ions are created. The SiClₓ⁻ ions are heavier than pure chlorine radicals or ions and thus tend to enhance the anisotropy of the etching compared to an etchant that is based on chlorine (Cl₂). Further, the generation of chlorine radicals can be better controlled using silicon tetrachloride gas as etchant.

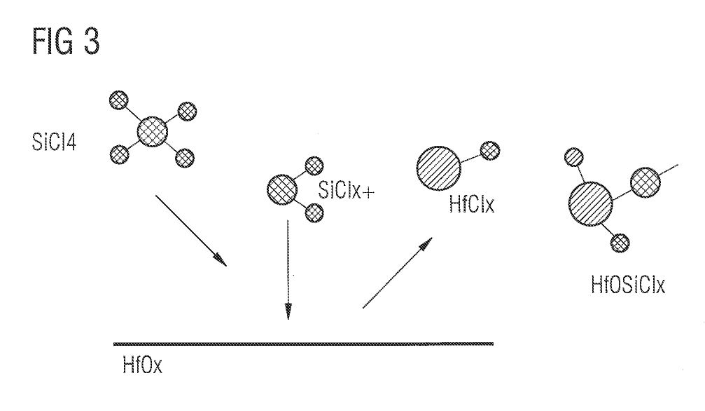

As further illustrated in FIG. 2, the silicon chloride ions react with the titanium nitride of layer 2 such that titanium chloride (TiClₓ) as well as titanium silicide chloride (TiSiClₓ) and nitrogen (Nₓ) is formed. In principle, this reaction mechanism similarly applies to the etching of layer 1 (comprising a high k metal oxide composition) with silicon tetrachloride, wherein, as describe above, an intermediate composition comprising a metal silicide oxide composition is generated. The etching of a high k metal oxide composition according to an embodiment of the invention is described in more detail in conjunction with FIG. 3.

Referring to FIG. 3, the etching of a layer comprising a high k material in the form of hafnium oxide (HfO) is illustrated. Of course, the illustrated etching mechanism can also apply to high k materials other than hafnium oxide. Moreover, the etching of the high k layer can be carried out in one step with the etching of the barrier layer as shown in FIG. 2 or another layer (e.g., a conductive layer) that is arranged at the high k layer.

Similarly to FIG. 2 an etchant comprising a silicon halogen gas in the form of silicon tetrachloride is used, wherein one of the silicon tetrachloride molecule is shown (SiCl₄). A plasma is ignited such that the silicon tetrachloride is decomposed and SiClₓ⁺ ions are generated which react with the high k layer. Two possible reaction paths are illustrated in FIG. 3.

One reaction path leads to the generation of hafnium chloride (HfClₓ), wherein another reaction path results in the generation of hafnium silicide oxide chloride molecules (HfOSiClₓ). The latter can be generated via an intermediate composition comprising hafnium silicide oxide (not shown) that occurs when the silicon tetrachloride (and the SiClₓ⁺ ions, respectively) react with the hafnium oxide of the high k layer.

It is noted, that the etchant used to etch the high k layer can of course comprise a plurality of components, i.e., it can contain further materials (gases) such as nitrogen (e.g., for side wall passivation) or chlorine in addition to the silicon halogen composition.

What is claimed is:

1. A method of fabricating an integrated circuit, the method comprising:
providing a layer that comprises a high k material in the form of a metal oxide composition; and
etching the layer using an etchant, the etchant comprising a silicon halogen composition.

2. The method according to claim 1, wherein the metal oxide composition comprises a transition metal oxide composition or a rare earth oxide composition.

3. The method according to claim 2, wherein the metal oxide composition comprises a hafnium oxide composition or a zirconium oxide composition.

4. The method according to claim 1, wherein the etchant comprises silicon chloride or silicon fluoride.

5. The method according to claim 4, wherein the etchant comprises silicon tetrachloride.

6. The method according to claim 1, wherein the layer comprises a gate dielectric of a transistor and wherein the metal oxide composition of the layer has a refractive index greater than a refractive index of silicon oxide.

7. The method according to claim 1, wherein the layer comprises a node dielectric of a capacitor and wherein the metal oxide composition of the layer has a refractive index greater than a refractive index of silicon oxide.

8. The method according to claim 1, further comprising etching a further layer using the etchant comprising the silicon halogen composition, wherein the further layer is arranged over the layer comprising the high k metal oxide composition.

9. The method according to claim 8, wherein the further layer comprises a diffusion barrier thwarting a diffusion from the layer comprising the high k metal oxide composition.

10. The method according to claim 9, wherein the layer comprising the high k metal oxide composition comprises a gate dielectric of a transistor and the further layer is disposed between the gate dielectric and a gate layer of the transistor.

11. The method according to claim 9, wherein the further layer comprises titanium nitride.

12. The method according to claim 8, wherein the further layer comprises a conductive material.

13. The method according to claim 12, wherein the layer comprising the high k metal oxide composition comprises a node dielectric of a capacitor and the further layer is to be used as an electrode layer of the capacitor.

14. The method according to claim 1, wherein the etchant further comprises nitrogen.

15. An integrated circuit fabricated with the method according to claim 1.

16. A method of fabricating an integrated circuit, the method comprising:
etching a layer that comprises a titanium nitride composition with an etchant, the etchant comprising a silicon halogen composition.

17. A method of fabricating an integrated circuit, the method comprising:
providing a layer comprising a high k material in the form of a metal oxide composition; and
etching the layer using an etchant, the etchant configured to create a metal silicon oxide composition with the metal oxide composition of the layer during the etching.

18. The method according to claim 17, wherein the metal oxide composition comprises a transition metal oxide or a rare earth oxide.

19. The method according to claim 18, wherein the etchant comprises a silicon halogen.

20. The method according to claim 19, wherein the etchant comprises silicon chloride or silicon fluoride.

21. The method according to claim 20, wherein the etchant comprises silicon tetrachloride.
